(19) United States
(12) Patent Application Publication
(10) Pub. No.: US 2010/0013042 A1
(43) Pub. Date: Jan. 21, 2010

(54) CMOS image sensor including tunable read amplifier

(76) Inventor: Juhan Kim, San Jose, CA (US)

Correspondence Address: JUHAN KIM, 5890 W. WALBROOK DR., SAN JOSE, CA, 95129, US

(21) Appl. No.: 11/934,870

(22) Filed: Nov. 5, 2007

(51) Int. Cl. H01L 27/14; H01L 27/00

(52) U.S. Cl. 257/458; 250/208.1; 257/461; 257/E27.122

(57) ABSTRACT

CMOS image sensor is realized, wherein a pre-amp amplifies the voltage of a photo detector, and a main amp amplifies the output of the pre-amp. And the pre-amp is adjustable for receiving the output of the photo detector, and also the main amp is adjustable for optimizing the output swing. With the adjustable amps, low sensitivity photo detector can be amplified more, and high sensitivity photo detector can be amplified less, which enables to adjust the gain of each amp from the low-sensitive to high-sensitive photo detector. The information for adjusting the amps is stored in the latches of the chip, wherein include laser-blown fuses or electric fuses. In doing so, the photo detector can be stacked over the access device. In particular, photo detector is repairable, wherein failed photo detector is replaced with non-failed photo detector.

### FIELD OF THE INVENTION

The present invention is related to CMOS image sensor. More specifically, CMOS image sensor includes tunable read amplifier and the failed photo detector is replaced with un-failed photo detector, in order to increase product yield.

### BACKGROUND OF THE INVENTION

CMOS (Complementary Metal-Oxide Semiconductor) image sensor has been developed for the image processing, such as digital cameras, camcorders, cellular phones and so on. The image sensor includes an image pickup pixel portion comprising a plurality of pixels arranged in a two-dimensional form, and a peripheral circuit portion disposed on the outside of the image pickup pixel portion. In each pixel of the image pickup pixel portion, floating diffusion portion as well as various MOS (Metal Oxide Semiconductor) transistors including a transfer transistor and an amplification transistor are typically provided. In this case, light incident on each pixel is subjected to photo-electric conversion by a photo detector or photodiode to generate a signal charge, the signal charge is transferred to the floating diffusion portion (which serves as a storage capacitor) by the transfer transistor, the variation of potential at the floating diffusion portion is detected by the amplification transistor, and the detected variation is converted into an electric signal and amplified, whereby signals from each pixel are output through signal wires to the peripheral circuit portion.

In addition, the peripheral circuit portion is provided with a signal processing circuit for applying a predetermined signal processing, for example, CDS (correlative double sampling), gain control, A/D (analog-to-digital) conversion, and so on, to the pixel signals from the image pickup pixel portion, and a driving control circuit for controlling the output of the pixel signals by driving each pixel in the image pickup pixel portion, for example, vertical and horizontal scanners, a timing generator, and so on. As a result, those circuit techniques enable to fabricate the image sensor in a single semiconductor chip.

In order to transfer the charges in the photo detector, source follower is used, as published in FIG. 1A, “Single-Chip CMOS Image Sensor for Mobile Applications”, IEEE Journal of Solid-State Circuits, Vol. 37, No. 12, December 2002. And more priors are shown as published, U.S. Pat No. 5,898,168, U.S. Pat. No. 6,215,113 and U.S. Pat. No. 5,920,345. As shown in the prior arts, the NMOS source follower includes a pull-up NMOS transistor 105 as a receive device, a current source 108 as an active load, and an NMOS transistor 107 as a selector. And one more amplifier is added, such that a PMOS source follower includes a pull-down PMOS transistor 109 as a receive device, and a current source 110 as an active load. In order to measure the intensity of the light, the cathode of the photo detector PD is reset by RX signal. Hence, the cathode 101 of photo detector PD is pre-charged by the reset device 104 through the transfer gate 102. Then, RX signal is lowered to turn off NMOS transistor 104. After then, the charge of the cathode 101 is transferred to a common node 103, When the select device 107 is turned on, the receive device 105 is turned on simultaneously, which sets up a current path from VDD to the active load 108, but the receive device 105 has high turn-on resistance with high body effect when the source node 106 is pulled up by the current path, and the applied voltage V1 between the gate 103 and the source 106 is also reduced. As a result, the gain of the source follower is limited. Furthermore, the output voltage (Vamp1) of the source follower is limited by the voltage drop of the NMOS transistor 105 because the NMOS transistor 105 is turned off when the node 106 is reached to VDD-VTN, where VTN is the threshold voltage of NMOS 105. Hence the output Vamp1 can be raised near VDD-VTN voltage only. And PMOS source follower is added to get more gain, but the output Vamp2 of the PMOS source follower is also limited by the threshold voltage of the PMOS transistor 109. And the maximum gain is near 1. Thus the prior art requires high sensitive photo detector is required, which also needs relatively wide area of the photo detector. In addition, the receive device 105 and select device 107 should be big in order to get more gain. Furthermore, the gain of the source follower is not tunable after fabricating.

Another prior art is illustrated, as shown in FIG. 1B, “A ¼ in 2M Pixel CMOS Image Sensor with 1.75Transistor/Pixel”, ISSCC 2004, 0-7803-8267-6/04. Four photo detectors share a source follower in order to reduce the pixel size. In doing so, the photo detector area can be increased slightly. And a floating diffusion (FD) is inserted, which serves as a storage capacitor to store the charges from the photo detector 151 (PD1) through NMOS transistor 152, when the read line (RL1) is asserted to VH level (high voltage). Before measuring, the photo detector is reset through the NMOS transistor 154 by RST signal. However, the source follower including a receive device 157 and select device 155 has low gain and limited swing. Furthermore, the gain of the source follower is not tunable after fabricating in the prior arts.

In this respect, there is a need for improving the amplifier portion of the CMOS sensor. In the present invention, tunable high gain amps are employed, in order to measure the voltage of the photo detector more efficiently. There are two stages for the amplification. The first amp is a pre-amp which is tunable, and the second amp is a main amp which is also tunable. More specifically, the present invention introduces methods and circuits to measure the voltage of the photo detector, in order to get high quality image sensor with reduced pixel area and chip area. In addition, the tunable high gain amps can achieve high yield because the amps can be even adjusted for the low sensitive photo detector, and the output swing can be adjusted to transfer the measured voltage to the sample and hold circuit.

In addition, the information for adjusting the gain of the amp is stored in the latch device of the chip, such as laser-blown fuse, electric fuse and nonvolatile memory. The programming method is similar to the prior art in order to program fuses, as published, U.S. Pat. Nos. 5,517,455 and 6,963,511. Thus each chip can be adjusted for the optimization, which increases product yield, such that the gain of the amps can be optimized when the process is deviated from the pre-determined performance.

In particular, failed photo detector is replaced with un-failed photo detector. In order to do so, the photo detectors are formed on the access device, which photo detector may have low sensitivity to the light intensity, but the gains can be adjusted for capturing the image. Hence, two photo detectors configure a pixel, which receives almost same light from object with fingered shape. And information for adjusting amps is stored in latches which include laser-blown fuses and electric fuses.

### SUMMARY OF THE INVENTION

In the present invention, CMOS image sensor including tunable read amplifier is realized, wherein a tunable amplifier serves as a pre-amp and another amplifier serves as a main amp. The pre-amp is adjustable for receiving the output of the photo detector, and also the main amp is adjustable for optimizing the output swing. With the adjustable amps, low sensitivity photo detector can be amplified more, and high sensitivity photo detector can be amplified less, which enables to adjust the gain of each amp from the low-sensitive to high-sensitive photo detector. The information for adjusting the amps is stored in the latches of the chip, wherein include laser-blown fuses or electric fuses.

By employing the tunable pre-amp and main amp, photo detectors are formed on the access device, which photo detector may have low sensitivity to the light intensity, but the gains can be adjusted for capturing the image. Hence, the two photo detectors configure a pixel. Each photo detector receives almost same light from the object with the fingered shape. Thus, failed photo detector is replaced with un-failed photo detector.

Tuning information for adjusting the gain of the pre-amp and the main amp is stored in the latch device of the chip. And the latch devices include laser-blown fuses, electrically blown fuses, or nonvolatile memories. Thus each chip can be adjusted for the optimization, which increases product yield, such that the gain of the amps can be optimized when the process is deviated from the predetermined performance.

Using tunable amplifier, any type of photo detector can be used as a image capturing device, such as amorphous photo detector, polysilicon photo detector, quantum dot photo-detector, and so on. In addition, the image sensor can be fabricated on the bulk wafer or SOI wafer, because the photo detector is stacked over the MOS transistors. Topping the photo detector is not directly related to the MOS transistor process, which is more flexible to fabricate the image sensor.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings which are incorporated in and form a part of this specification illustrate embodiments of the invention and together with the description, serve to explain the principles of the invention.

FIG. 1A illustrates a prior art, wherein includes source follower. FIG. 1B illustrates another prior art, wherein four photo detectors share an amp, in order to reduce area.

FIG. 2A illustrates an amplifier which includes active load. And FIG. 2B illustrates I-V curve of FIG. 2A. And FIG. 2C illustrates an amplifier which includes resistive load. And FIG. 2D illustrates I-V curve of FIG. 2C, according to the teachings of the present invention.

FIG. 3 illustrates the image sensor circuit including amps and photo detectors, according to the teachings of the present invention.

FIG. 4A illustrates I-V curve for the pre-amp, and FIG. 4B illustrates I-V curve of the main amp, when the sensitivity of the photo detector is high, according to the teachings of the present invention. FIG. 4C illustrates I-V curve for the pre-amp, and FIG. 4D illustrates I-V curve of the main amp, when the sensitivity of the photo detector is low, according to the teachings of the present invention.

FIG. 5 illustrates tunable main amp wherein includes selectable active load, according to the teachings of the present invention.

FIG. 6 illustrates tunable main amp wherein includes variable active load, according to the teachings of the present invention.

FIG. 7 illustrates an alternative configuration including current mirror, according to the teachings of the present invention.

FIG. 8A illustrates the latch circuit including laser-blown fuse, to store the information for the select device, according to the teachings of the present invention. FIG. 8B illustrates the latch circuit including electric fuse, to store the information for the select device, according to the teachings of the present invention.

FIG. 9A illustrates multiplexer circuit to select the fuse output or test input. FIG. 9B illustrates selectable bias circuit (for the variable active load of FIG. 3), according to the teachings of the present invention.

FIG. 10 illustrates a multiplexer circuit to select fuse data or test input, according to the teachings of the present invention.

FIG. 11A illustrates a multiplexer circuit to select fuse data or test input for row repair, according to the teachings of the present invention. FIG. 11B illustrates a multiplexer circuit to select the read lines, according to the teachings of the present invention.

FIG. 12 illustrates an example block diagram of the image area, according to the teachings of the present invention.

FIG. 13 illustrates a cross section for a pixel cell, according to the teachings of the present invention.

FIG. 14 illustrates an example cross section on the bulk for a pixel cell, according to the teachings of the present invention.

FIG. 15 illustrates an example cross section on the SOI wafer for a pixel cell, according to the teachings of the present invention.

FIG. 16 illustrates an example pixel structure using p-i-n diode, according to the teachings of the present invention.

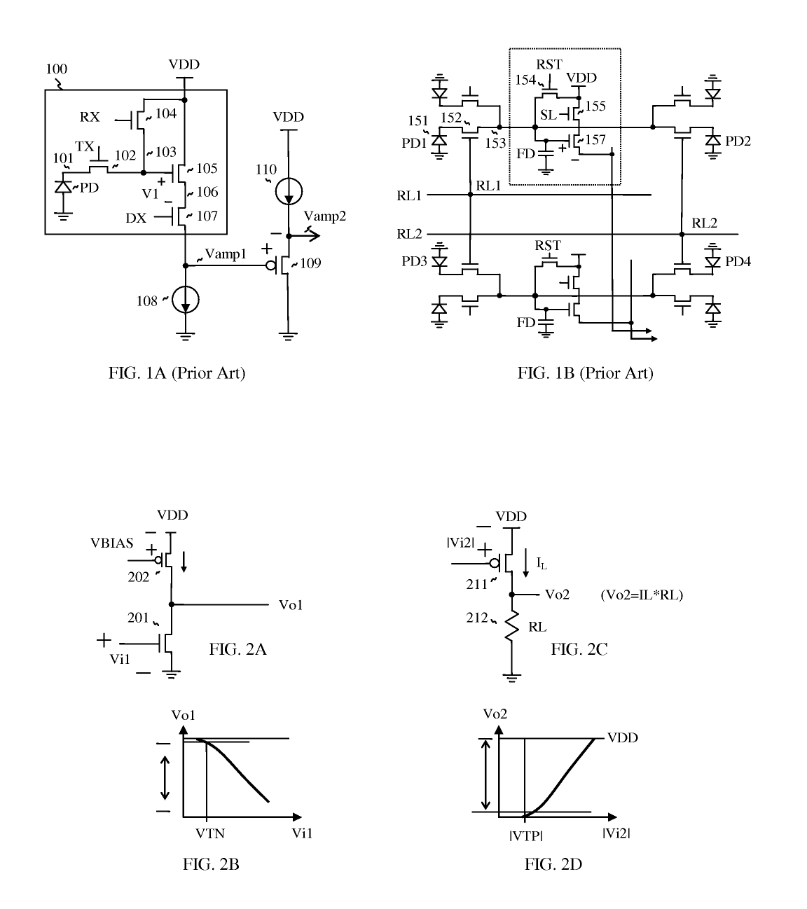

### DETAILED DESCRIPTION OF PREFERRED EMBODIMENT(S)

Reference is made in detail to the preferred embodiments of the invention. While the invention is described in conjunction with the preferred embodiments, the invention is not intended to be limited by these preferred embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, as is obvious to one ordinarily skilled in the art, the invention may be practiced without these specific details. In other instances, well-known methods, procedures, components, and circuits have not been described in detail so that aspects of the invention will not be obscured.

The present invention is directed to CMOS image sensor, wherein high gain amplifiers are employed for amplifying captured charge from the photo detector. In order to obtain high gain, an amplifier is used as shown in FIG. 2A, wherein an NMOS transistor 201 serves as a receive device and NMOS transistor 202 serves as an active load with bias voltage VBIAS, and input Vi1 is asserted to NMOS transistor 201. I-V curve is illustrated in FIG. 2B, wherein the output Vo1 is near VDD voltage when input Vi1 is at zero, and the output is reduced as the input Vi1 increases. Thus the output is inverted, and the gain is higher than that of the source follower, because the input Vi1 changes the turn-on resistance of the receive device 201 from low to high resistance. The output Vo1 reflects gate input Vi1, which realizes high gain with the common source amplifier. In contrast, gate voltage of the source follower follows the output voltage (not shown), which limits gain. In order to get high output swing, the receive device 201 should have wide channel, because the active load 202 is always turned on and provides positive charges to output node Vo1, which is a limitation to get full swing. Thus, another stage is used as a main amp, as shown FIG. 2C, wherein the PMOS transistor 211 serves as receive device and the resistor 212 serves as a load, which form a PMOS amplifier. In FIG. 2D, I-V curve is illustrated wherein the output Vo2 is at near zero when input Vi2 is at zero. The output swing depends on the load resistance, as Vo2=IL*RL. Hence, the load resistance can be tunable for the use.

In FIG. 3, detailed image sensor circuit including amps and photo detectors is illustrated. The active pixel 300 is connected to the reset circuit 321 and active load 330 through PMOS switch 323, so that the active load 330 is connected to the receive device 305 in the active pixel 300 through the PMOS 323 and NMOS 306, which configure an amplifier and serves as a pre-amp. The output of the pre-amp is transferred to the main amp 370, wherein PMOS transistor 372 serves as a receive device of the main amp, and resistor 373 serves as a load of the main amp when the resistor 373 is selected by the select device 374 in resistor block 371. There are multiple photo detectors in the active pixel 300, such that one access device including receive device 305, select device 306 and reset device 304 is shared by four photo detectors, PD1A, PD1B, PD2A and PD2B through transfer gates 302, 302′, 352 and 352′, respectively, and another access device including receive device 315, select device 316 and reset device 314 is shared by four photo detectors, PD3A, PD3B, PD4A and PD4B through transfer gates 312, 312′, 362 and 362′, respectively, where the common node 303 and 313 are also shared, respectively.

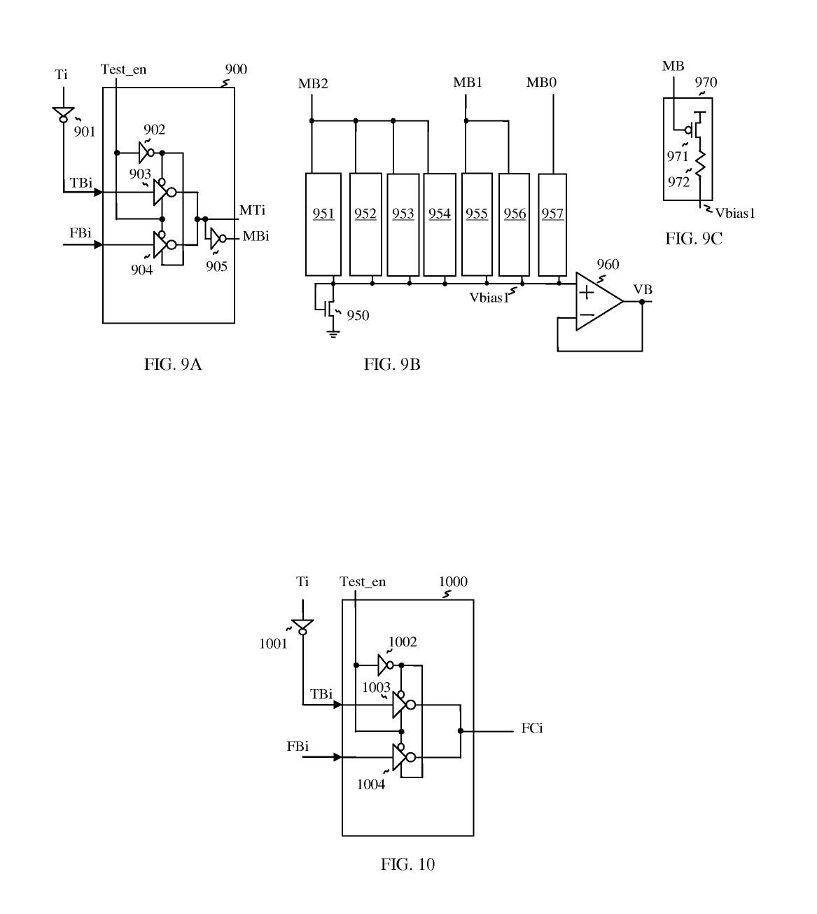

Before measuring the voltage of the photo detector PD1A, the cathode 301 of the photo detector, a charge collect capacitor C1, and a charge reserve capacitor C2 are reset by the predetermined reset voltage VRST, when the transfer gates 302 is turned on by the read line (RL1), and reset control signal RST is asserted to high in order to turn on the transfer gate 304, and also RSTB signal is asserted to low to turn on the PMOS transfer gate 321. During reset, the cathode 301 and a common node 303 are charged to VRST voltage, and then the transfer gates 304 and 321 are turned off. After pre-determined exposure time, the voltage of the cathode 301 is lowered, depending on the light intensity. Thus, the generated electrons are transferred to the common node 303. After then, the pre-amp 330 is activated to measure the voltage of the common node 303, by turning on the select device 306 with select signal SL. And also ACTB signal is asserted to low in order to turn on the transfer gate 323 and active signal ACT is asserted to high in order to turn off the pre-charge device 324. In doing so, a current path is set up from the active load 331 to the receive device 305, when the select device 332 is turned on by low state of MBi signal which is generated from fuse circuit (in FIG. 9A). There are multiple active loads in order to adjust the strength of the pull-up, and the active load transistor 331 is biased by a predetermined voltage (Vbias), which configures first tunable load device. And the pre-amp output Vout1 is transferred to the main amp 370, and the main amp is also adjusted for optimizing the output swing by selecting the resistance of the load with RTi signal. Alternatively, MOS transistor 381 can be used as active load, such that the active load 384 is controlled by the bias voltage VB, the select device 383 is selected by the select signal 382.

In order to adjust the gain of the pre-amp, multiple loads are added, such that at least one active load is selected by MBi signal, and each active load 330, 330A and 330B is identical, but the selected signals are differently connected to the fuse latch (as shown in FIG. 8A, where MBi becomes MBi signal). In the similar manner, the main amp has multiple loads, such that that at least one load is selected by the RTi signal, and each load 371, 371A and 371B is identical, but the select signal RTi is differently connected to the fuse latch (as shown in FIG. 8A, where MTi becomes RTi signal). In addition, biased active loads are available to adjust the main amp, such that at least one load is selected by the signal 382, and each load 381, 381A and 381B in bottom-right drawing as shown in FIG. 3 is identical, but the select signal 382 is differently connected to the fuse latch (as shown in FIG. 8A, where MTi becomes the signal 382), and the bias signal VB is generated by the bias circuit (as shown in FIG. 8B). And more loads are added in the actual design.

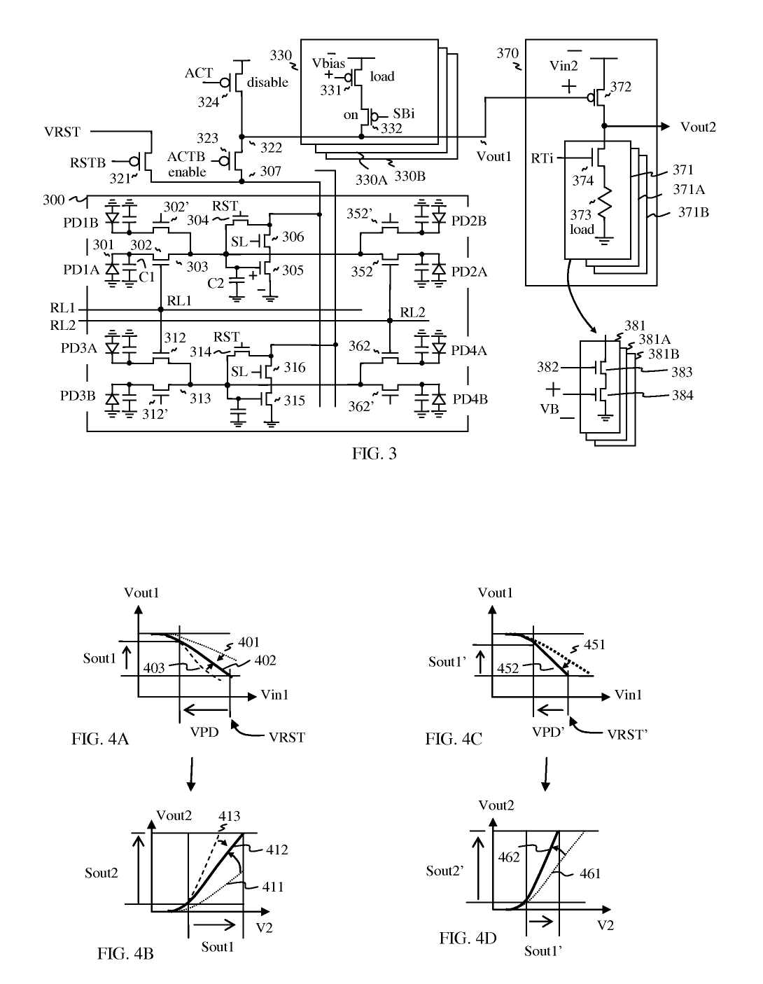

Referring now to FIG. 4A in view of FIG. 3, I-V curve of the pre-amp illustrated, in order to explain the operation of the pre-amp. When the photo detector generates the voltage difference VPD, the pre-amp generates the output swing Sout1. The optimum gain 402 is obtained. However, the gain can be deviated from the target value because of various reasons, such as fab transition or applying new process and so on. When the gain is too low, as shown 401 in FIG. 4A, the strength of the active load 330 should be reduced by reducing the number of the active load. Hence the gain is increased. Or when the gain 403 is too high, the strength of the active load 330 should be increased by increasing the number of the active load, which reduces the gain of the pre-amp. In doing so, the output swing of the pre-amp is adjusted. But, the output swing of the pre-amp is limited by the detected voltage of the photo detector. In this respect, the next stage amp is needed in order to obtain full swing output. In addition, two stage amps are more efficient to obtain high gain, and more flexible to adjust.

Referring now to FIG. 4B in view of FIG. 3, I-V curve of the main amp is illustrated. The output of the pre-amp Sout1 is transferred to the main amp. Hence the output swing of the main amp Sout2 is almost full swing, when the main amp has optimum gain 412 in FIG. 4B. And the output Vout2 (in FIG. 3) of the main has relatively low parasitic capacitance because the output Vout2 is transferred to the adjacent next stage, such as sample and hold circuit which is not shown because it is not a scope of the present invention. In contrast, the output Vout1 of the pre-amp has high parasitic capacitance with multiple pixels in a column. The narrower swing of the pre-amp output, less consuming the charging/discharging current, but the accuracy will be degraded. The main output swing is also tunable to fit for the next stage, such that when the gain 411 is too low, the number of the load is reduced to obtain optimum gain curve 412 and high swing output Sout2. Or when the gain 413 is too high, the number of the load is increased to obtain optimum gain curve 412.

Referring now to FIG. 4C, I-V curve of the pre-amp is illustrated. When the sensitivity of the photo detector is low, the pre-amp can be adjusted to get more gain, which means that any type of image sensor can be adjusted for obtaining optimum output swing. This is one of the advantages of using tunable pre-amp in the present invention. And also the main amp can be adjusted to fit the output swing in order to transfer to the next stage. In doing so, the tunable amps are useful to sense the light intensity from low sensitive photo detector to high sensitive photo detector, and which can reduce chip area as well with reduced photo detector area because a small photo detector generates low voltage output. Furthermore, amorphous photo detector, polysilicon (polycrystalline silicon) photo detector, quantum dot photo-detector (as published, U.S. Pat. No. 5,293,050 and U.S. Pat. No. 6,906,326), and any light-sensitive material can be used as the photo-detector in the present invention, whether the detectors are less sensitive or very sensitive to the light intensity. Depending on the sensitivity of the photo detector, the reset voltage is changed. For example, the node of the photo detector is charged to VRST′ as shown in FIG. 4C, and when the gain of the pre-amp is deviated to low, the pre-amp is adjusted to optimum gain 452 from low gain 451 in FIG. 4B. As a result, the range of the photo detector is adjusted as VPD′ for the low sensitive photo detector. And the output Sout1′ may be slightly reduced, but the main amp output Sout2′ in FIG. 4D is almost same as the output Sout2 of the high sensitive photo detector as shown in FIG. 4B. In order to fit the output swing, the gain of the main amp is also adjusted to optimum gain 462 from low gain 461.

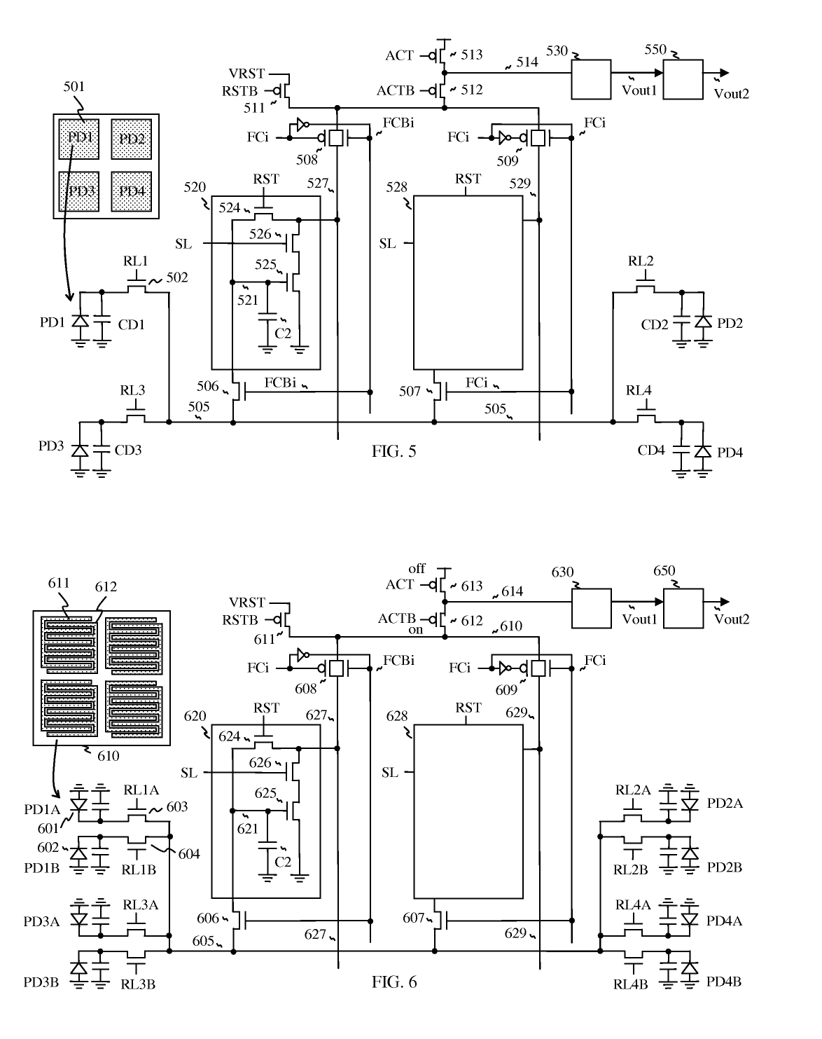

Furthermore, photo detector can be reduced, which enables to put two photo detectors in a pixel area, in order to repair one of failed photo detector. In FIG. 5, an example circuit for repairing access device is illustrated, wherein two access devices 520 and 528 are shared by four photo detectors PD1, PD2, PD3 and PD4, the left access device 520 can access the photo detectors PD1, PD2, PD3 and PD4, or the right access device 528 can also access the photo detector PD1, PD2, PD3 and PD4, depending on the polarity of the select signal FCi. For example, when the read line 1 (RL1) is asserted to high, PD1 is accessed through transfer gate 502 and common line 505. And when FCi signal is low, the left access device 520 is activated through a transfer gate 506 and another transmission gate 508 which is connected to the column line 527. Or when FCi signal is high, the right access device 528 (same circuit as 520 in FIG. 5) is activated through a transfer gate 507 and another transmission gate 509 which is connected to the column line 529. This circuit is implemented by forming the photo detectors on the access devices, wherein the photo detector 501 (separate figure in the upper left as shown in FIG. 5) serves as PD1. Hence, two access devices can be formed under four photo detectors PD1, PD2, PD3 and PD4, which gives enough space to put the MOS transistors, with shared access devices. And the information for the select signal FCi is stored in the latch device which includes fuses. In addition, the select signal is controllable for the test mode in order to measure the optimum operation. After the select signal FCi selects the access device, the pre-amp 530 (including active loads as shown 330 in FIG. 3) amplifies the voltage of the common node 521 (in access device 520) which stores the charges generated from the photo detector in the charge reserve capacitor C2, and there is one more capacitor CD1 as a charge collect capacitor under the photo detector. The capacitors CD1, CD2, CD3 and CD4 can be formed with normal dielectric and ferroelectric dielectric material to get more capacitance within the limited space alternatively, which gives more flexibility for the routing between the signals. However, the total capacitance value (including two storage capacitor and parasitic capacitor in the common node 521) should be carefully decided, for example, high capacitance is better for high sensitive photo detector, in contrast, low capacitance is good for low sensitive photo detector, in order to get optimum voltage input of the pre-amp 530. The amps are activated, when ACT signal turns off pull-up device 513 and ACTB signal turns on the transfer gate 512. And the output of pre-amp is transferred to the main amp 550. And during reset, RSTB signal is lowered and turns on transfer gate 511. Thus, reset voltage VRST is transferred to the photo detector node and the common node of the capacitor.

In FIG. 6, more flexible repair circuit is illustrated, in order to repair a failed photo detector, as the present invention, wherein photo detectors configure pixel 610 and the photo detector 601 is layout 611, the photo detector 602 is layout 612 (separate figure in the upper left as shown in FIG. 6), for example, which are fingered in shape. In doing so, the detected light intensity is almost same with tightly coupled shape. The fingered type photo detector is less sensitive. Moreover, tunable pre-amp and tunable main amp can optimize the gain, and generate optimum output swing to send to the next stage, such as sample and hold circuit. In order to repair failed PD1A, the read line RL1A is lowered to turn off transfer gate 603. Instead of RL1A, RL1B is asserted, thus un-failed PD1B is accessed through transfer gate 604. And then, the other operations are the same as FIG. 5. The access device 620 can be selected when FCi signal is at low. For example, when the read line RL1B is asserted to high, PD1B is accessed through transfer gate 604 and common line 605. Hence, the left access device 620 is activated through a transfer gate 606 and another transmission gate 608 which is connected to the column line 627. And the left access device 620 including receive device 625, select device 626 and reset device 624 is shared by eight photo detectors, PD1A, PD1B, PD2A, PD2B, PD3A, PD3B, PD4A and PD4B through the common node 605. When FCi signal is at high, the right access device 623 (same circuit as the left access device 620) is activated through a transfer gate 607 and another transmission gate 609 which is connected to the column line 629. After the select signal FCi selects one of access devices, the pre-amp 630 amplifies the voltage of the common node 614 from node 610, when the PMOS 611 and 613 are turned off and PMOS 612 is turn on. After then, the main amp 650 receives the output (Vout1) of pre-amp and amplifies the voltage. Thus the main amp output (Vout2) is generated by the main amp 650.

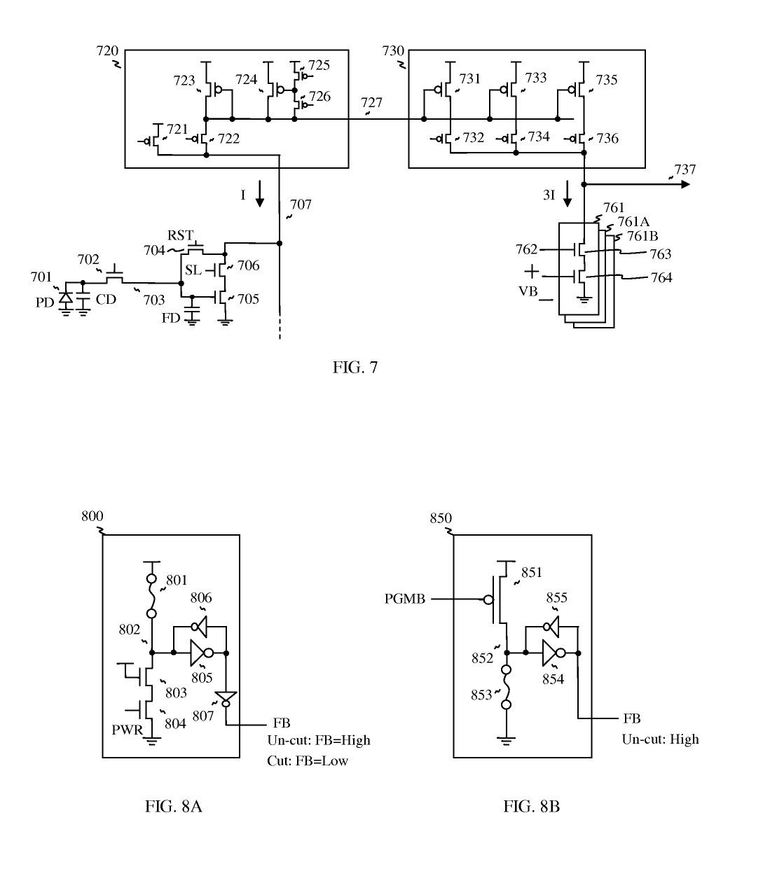

In FIG. 7, an alternative configuration including current mirror is illustrated, wherein photo detector 701 captures light intensity, the charges from the photo detector is transferred to pre-amp 720 through column line 707, such that receive transistor 705 serves as amplify device and transistors 723 and 724 serve as an active load, while select transistor 706 and enable transistor 722 are turned on, and select transistor 725 is turned on, deselect transistor 726 is turn off. The amplify device 705 receives voltage output from the photo detector 701 through transfer transistor 702 and common node 703. And the charges are stored in a floating capacitors CD and FD. Then, current mirror 731, 733 and 735 repeat the current flow from pre-amp output 727, but the amount of current through the main amp is multiplied by number of the current mirror. For example, the current mirror 731, 733 and 735 have same width and length of the active load device 723, so that each current mirror flows same amount of current that the active load device 723 flows. Hence, total current through the main amp 730 is increased to three times higher than that of the amplify device 705. More current mirrors can be added to increase the amount of current, which realizes high gain. And, the main amp is also adjusted to get optimum output swing 737, such that tunable active load devices 761, 761A and 761B are selectable, and the active load device 764 is biased by a voltage VB, which voltage is generated a bias circuit as shown in FIG. 9B. Thus, active load is selected by a select transistor 763 with select signal 762. Furthermore, the conventional source follower can be used as pre-amp and main amp with select transistors for adjusting as alternative configuration (not shown), even though gain is lower than common source amplifier as explained above.

In FIG. 8A, the latch device 800 is illustrated in order to store the information for adjusting the amps, and also store the information to repair the photo detectors and the access devices, wherein the laser-blown fuse 801 is connected to the pull-down transistor 803, the pull-down transistor 804 is connected to the pull-down transistor 803, the inverter 805 is connected to the fuse node 802, and feedback inverter 806 is connected to the output of inverter 805 to keep the fuse data. Hence, the output FB is inverted by inverter 807. During power-up, PWR signal is asserted to high. Hence, the fuse node 802 is lowered to ground when the fuse 801 is cut, but the fuse node 802 keeps high when the fuse is not cut. When the fuse is not cut, the fuse output FB is high.

Alternatively, electric fuse can be used, as shown in FIG. 8B, in order to store the information for adjusting the amps, wherein the electric fuse 853 is connected to the fuse node 852, PMOS pull-up 851 is connected to the fuse node 852, and inverter 854 is connected to the fuse node 852, the feedback inverter 855 is connected to the output of the inverter 852 in order to keep the fuse data, and the output FB is connected to the inverter 854. In order to melt the electric fuse by high current or high voltage, PMOS 851 is turned on by asserting PCMB signal to low. And also high voltage is applied to the supply of PMOS 851. After melting, the fuse data is stored in the fuse node 852, and the fuse node 852 is high. Thus, FB output is low, when the electric fuse is cut. When the fuse is not cut, the fuse output FB is high.

In FIG. 9A, multiplexer circuit 900 is illustrated, in order to select the fuse data or test input. In the normal operation, the tunable amps receive the fuse data, wherein the clocked inverter 904 is turned on, and the fuse output (FBi) is transferred to the multiplexer output. But during test, the test enable (Test_en) signal selects test input (Ti) in order to measure the gain and the functionality. When Test_en signal is asserted to high, test input is transferred to adjust the amps, such that test input is inverted by the inverter 901, and the clocked inverter 903 is turned on, when test enable signal is asserted to high and the output of the inverter 902 is lowered. Thus, test input is transferred to the multiplexer output MTi, and inverted output MBi through an inverter 905. Otherwise, fuse data is transferred to the output MTi and MBi through clocked inverter 904, during normal mode. In this manner, the test mode can measure the optimum gain, after then the information can be stored in the fuses, wherein detailed method is not described in the present invention because the method is similar to the fuse cutting method for repairing semiconductor memory with the conventional techniques. Thus each chip can be adjusted for obtaining gain, which increases yield.

In FIG. 9B, the decoder circuit is illustrated to set up the bias voltage VB in FIG. 3, wherein the pull-up circuit 957 is connected to MB0 signal from the latch device (800 in FIG. 9A). More detailed circuit of the pull-up circuit 957 is shown in 970 in FIG. 9C, the select device 971 is controlled by MB signal, and a resistor 972 is connected to the select device. And other pull-up circuits 956, 955, 954, 953, 952, 951 are the same circuit as 970 in FIG. 9C. Further, the pull-up circuit 955 and 956 are connected to MB1 signal, and the pull-up circuit 951, 952, 953 and 954 are connected to MB2 signal, where MBi signal becomes MB2, MB1 and MB0 signal with multiple fuse circuits (not shown). When MB0 is selected to low while the others are high, only one pull-up device 957 is turned on by MB0 signal. Thus, Vbias1 is lowest value with low pull-up current. But when all signals MB2, MB1 and MB0 signals are lowered, Vbias1 value is highest value with strong pull-up current, where all the pull-up circuits 951, 952, 953, 954, 955, 956 and 957 are identical. Operational amp 960 serves as a buffer for transferring Vbias1 signal, and generates VB signal, wherein the operational amp is conventional type, thus there is no need of detailed schematic for the operational amp. In this manner, all the combinations can be selected by the binary-weighted decoder.

In FIG. 10, the multiplexer circuit to generate the column repair information is illustrated, in order to select the access device, wherein the operation is the same as FIG. 9A, and the repair information FB is stored in the latch device as shown in FIG. 8A or 8B. Hence, the repair information is transferred from the fuse to the repair select device by the multiplexer circuit 1000. In contrast, test inputs are selected when test enable signal (Test_en) is asserted to high. The column repair data FCi is transferred to the pixel cell and pre-amp, as shown FIG. 5 and FIG. 6. When Test_en signal is asserted to high, test input is inverted by the inverter 1001, and then the clocked inverter 1003 is turned on, when test enable signal is asserted to high and the output of the inverter 1002 is lowered. Thus, test input is transferred to the multiplexer output FCi through clocked inverter 1003, during test mode. Otherwise, fuse data (FBi) is transferred to the output FCi through clocked inverter 1004 for the column repair, during normal mode.

Similarly, row repair information is stored in the fuses, and selected by the multiplexer circuit 1100, as shown FIG. 11A. When Test_en signal is asserted to high, test input (Ti) is inverted by the inverter 1101, and then the clocked inverter 1103 is turned on, when test enable signal is asserted to high and the output of the inverter 1102 is lowered. Thus, test input is transferred to the multiplexer output FRi through clocked inverter 1103, during test mode. Otherwise, fuse data (FBi) is transferred to the output FRi through clocked inverter 1104 for the row repair, during normal mode. After then, the multiplexer output FRi is transferred to the row decoder as shown FIG. 11B. The NAND gate 1151 receives row addresses RA0, RA1, and RAi, and generates output 1152. And then, the multiplexer output FRi selects one of read lines, such that RL1A signal is selected in order to select PD1A (in FIG. 6) when FRi signal is low, or RL1B signal is selected in order to select PD1B (in FIG. 6) when FRi signal is high. The NAND gate output 1152 is transferred by the clocked inverter 1153 and 1154 depending on the FRi signal. During unselected, one of pull-down transistor 1155 and 1156 is turned on and the unselected read line is at ground level.

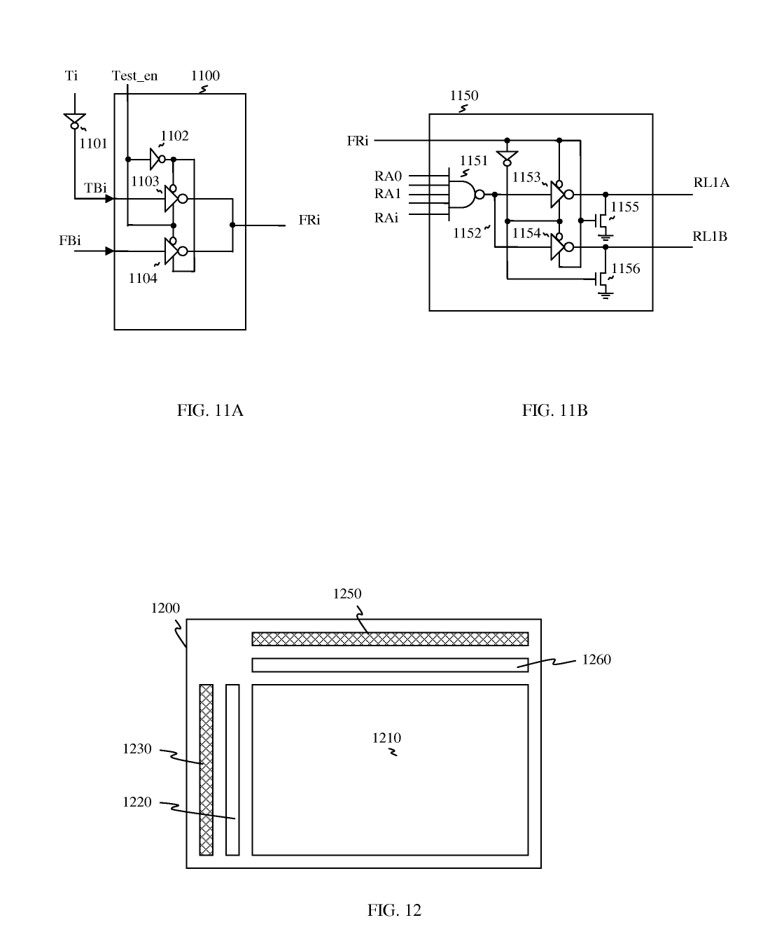

In FIG. 12, a block diagram of the image area 1200 is illustrated, wherein a pixel cell array block 1210 is located in the bottom, the row decoder block 1220 is placed in left of the pixel cells, a row fuse block 1230 including fuses for row repair is placed next to the row decoders, a column amp block 1260 including the pre amp and the main amps is placed in top of pixel cells, and a column fuse block 1250 including fuses for the column repair and for adjusting amps.

### Methods of Fabrication

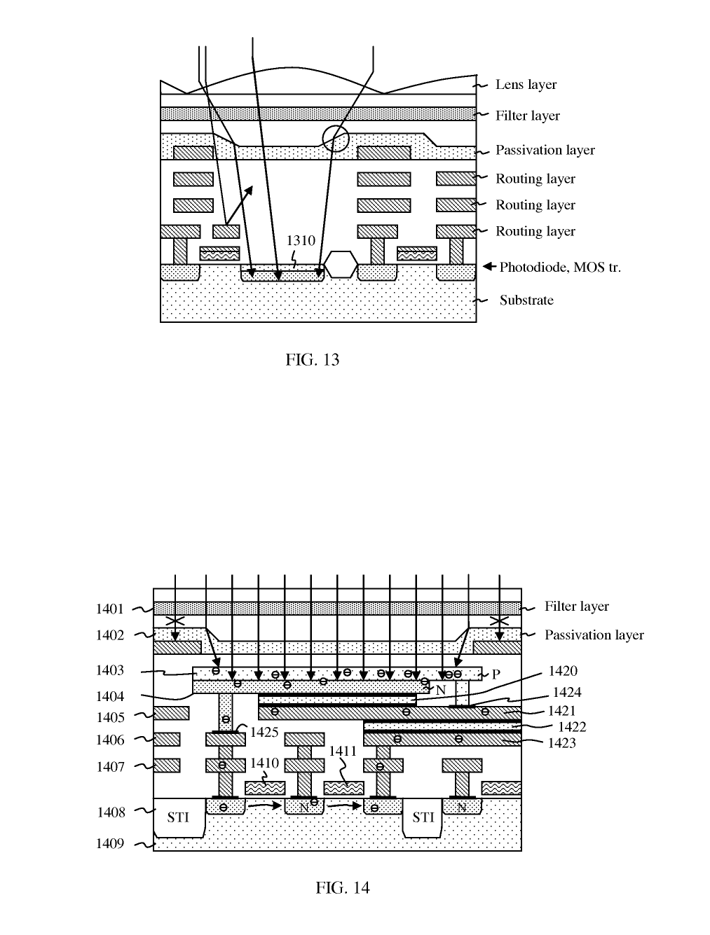

The photo detector (photodiode) 1310 of the pixel cell can be formed on the surface of the bulk, as shown in FIG. 13, with conventional structure. However, surface type photo detector has many disadvantageous, such as, non-flat passivation film, low sensitivity with limited fill factor, and poor light focusing. As published, “A 3.9 um Pixel Pitch VGA format 10b Digital Image Sensor with 1.5 Transistor/Pixel”, 0-7803-8267-6/04, IEEE International Solid-State Circuits Conference, 2004. Furthermore, one major drawback is that failed pixels can not be replaced with un-failed pixels. In contrast, usually failed memory cells can be replaced with un-failed memory cells using redundancy scheme in the conventional semiconductor memories. In order to replace failed pixel cells as semiconductor memories, two photo detectors are formed on the access devices and the sensitivity of the photo detector may be decreased, but the tunable amps can optimize the final output to transfer to the next stage. Hence, the low sensitive photo detectors can be formed on the MOS transistor with low temperature, such as amorphous photo detector, polysilicon diode, quantum dot and others. There is a prior art to form the photo detector on the CMOS circuitry, as published, U.S. Pat. No. 4,868,623, U.S. Pat. No. 6,709,885 and U.S. Pat. No. 7,030,551 as references. The present invention uses similar fabrication method. Thus detailed process steps and material related data are not described in the present invention.

In FIG. 14, an example pixel structure is illustrated, in order to realize repairable image sensor. The photo detector is formed on the MOS transistors, wherein the p-type anode 1403 is formed on the n-type cathode 1404, and a charge collect capacitor 1420 is formed under the n-type node 1404 with the ground line 1421, which capacitor may include buffer layer between the routing layers 1421 and 1423 in order to form a capacitor. The p-type anode 1403 is connected to the ground line 1421 through ohmic contact region. 1424. And insulating layer for the capacitor can use normal dielectric and ferroelectric dielectric material. The charges of the cathode 1404 are collected in the charge collect capacitor 1420, and the charges are re-distributed with the charge reserve capacitor 1422 when the transfer gate 1410 and 1411 (equivalently transfer transistor 502 and 506 in FIG. 5) through ohmic contact 1425 and conduction layers. In order to capture good quality image, the sensitivity of the photo detector and total capacitance of the photo detector node should be optimized, such that the charge collect capacitor 1420 and the charge reserve capacitor 1422 can be decreased or increased, depending on the sensitivity of the photo detector, and also insulation material can be carefully selected for the fabrication. And then, the pre-amp and the main amp should be adjusted for obtaining optimum output by the fuse setting. The charges of the photo detector node 1404 are transferred to the common node 1423 when the transfer gate 1410 and the select device 1411 for row repair are turned on. And the pixel cell includes other layer, such as, the filter layer 1401, the passivation layer 1402, the routing layer 1405, 1406 and 1407, STI (Shallow Trench Isolation) layer 1408, and the MOS transistors are formed on the surface of the substrate 1409. Thus, two photo detectors can be formed on the MOS transistor with the fingered shape as explained above in FIG. 6. Furthermore, the photo detector layer may be thin film. Also capacitor layers may be very thin.

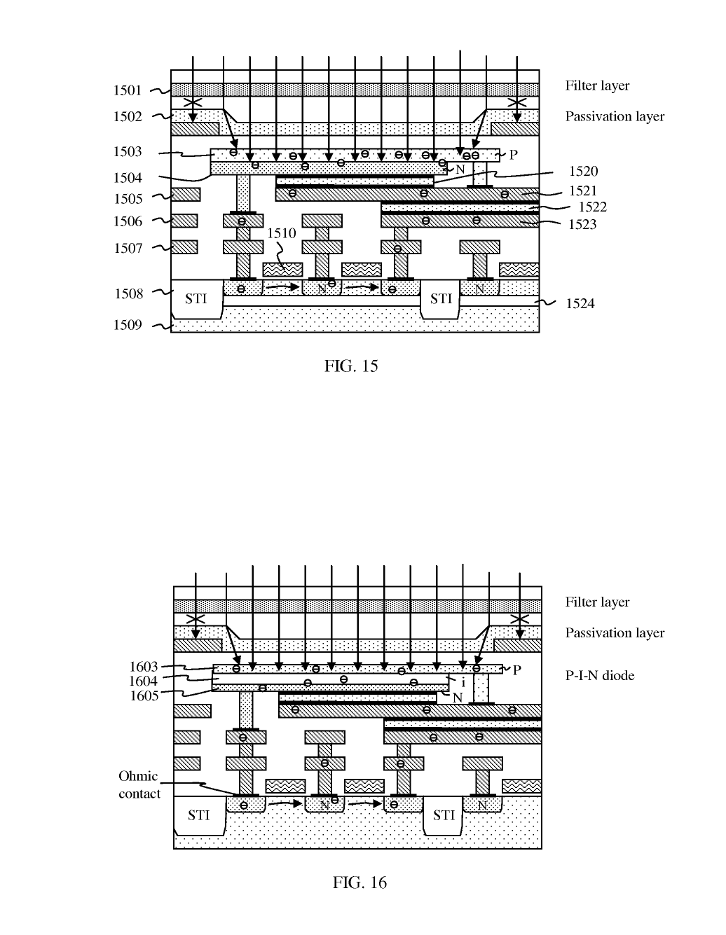

In FIG. 15, an example pixel structure on the SOI wafer is illustrated, in order to realize the repairable image sensor. The photo detector and the access device are formed on the SOI wafer, wherein the structure is basically the same as FIG. 14, except the MOS transistor on the buried oxide 1520, the p-type anode 1503 is formed on the n-type cathode 1504, and a storage capacitor 1520 is formed under the n-type node 1504 with the ground line 1521. The charges of the photo detector node 1504 are transferred to the common node 1523 when the transfer gate 1510 and the select device 1511 for row repair are turned on. And the pixel cell includes other layer, such as, the filter layer 1501, the passivation layer 1502, the routing layer 1505, 1506 and 1507, STI (Shallow Trench Isolation) layer 1508, and the MOS transistors are formed on the surface of the substrate 1509.

In FIG. 16, an example pixel structure using p-i-n diode is illustrated, wherein p-i-n (p-doped/intrinsic/n-doped) diode is used as the photo-detector. The p-i-n layers formed from the formation of the n-doped amorphous silicon conductor 1605, intrinsic amorphous silicon layer 1604, and the p-doped amorphous silicon top conductor 1603, form a p-i-n junction (referred to as pin diode) photo detector. And the other structures are the same as above.

The foregoing descriptions of specific embodiments of the invention have been presented for purposes of illustration and description. They are not intended to be exhaustive or to limit the invention to the precise forms disclosed. Obviously, many modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

What is claimed is:

1. An imaging device comprising:
a pixel cell wherein a photo detector is connected to a transfer transistor;
an access device wherein a common node is connected to the transfer transistor of the pixel cell, a reserve capacitor is connected to the common node, a reset transistor is connect to the common node, an amplify transistor receives the common node voltage, a select transistor is serially connected to the amplify transistor, and the select transistor is connected to a column line;
a pixel column wherein multiple pixel cells are connected to the access device, and the access device is connected to the column line;
a pre-amp wherein first tunable loads are serially connected to first tuning transistors, and the first tuning transistors are connected to the column line through enable transistor, and the first tunable loads are selected by first tuning transistors, and the first tuning transistors configure pre-amp output;
a main amp wherein a receive transistor receives the pre-amp output, and the receive transistor is connected to second tuning transistors; and the second tuning transistors are serially connected to second tunable loads; and
the second tunable loads are selected by the second tuning transistors, and the second tuning transistors configure main amp output; and
fuse latches which store tuning information for the first and the second tuning transistors; and
multiplexer circuits transferring the tuning information to the first and the second tuning transistors from the fuse latches or external test inputs.

2. The imaging device of claim 1, wherein the pre-amp includes tunable active loads; and the tunable active loads receive bias voltage from a bias circuit; and the tunable active loads are serially connected to tuning transistors; and the tuning transistors are connected to the column line through enable transistor in order to configure an amplifier connection with the amplify transistor of the access device; and the tunable active loads are selected by the tuning transistors; and the tuning transistors configure pre-amp output; and tuning information for the tuning transistors is stored in the fuse latches.

3. The imaging device of claim 1, wherein the main amp includes a tunable amplifier; more specifically, a receive transistor receives the pre-amp output; and second tunable loads are connected to the receive transistor through tuning transistors; and the second tunable loads are selected by the tuning transistors, and the tuning transistors configure main amp output; and tuning information for the tuning transistors is stored in the fuse latches.

4. The imaging device of claim 1, wherein the pre-amp includes tunable active loads; and
the main amp includes a current mirror which is configured by receiving gate voltage of the tunable active loads of the pre-amp; and current flow through the current mirror depends on channel width and length of the current mirror; and the current mirror is connected to second tunable loads; and tuning information for the tunable active loads and the second tunable loads are stored in the fuse latches.

5. The imaging device of claim 1, wherein the pre-amp includes tunable active loads; and
the main amp includes tunable current mirrors which are configured by receiving gate voltage of the tunable active loads of the pre-amp; and current flow through the tunable current mirrors depend on channel width and length of the tunable current mirrors; and the tunable current mirrors are connected to second tunable loads; and tuning information for the tunable active loads, the tunable current mirrors and the second tunable loads are stored in the fuse latches.

6. The imaging device of claim 1, wherein the pixel column includes multiple pixel cells and an access device; and multiple pixel cells are connected to an access device; and the access device is connected to the column line; and failed pixel cell is replaced with un-failed pixel cell by turning on the transfer gate of the un-failed pixel cell while the transfer gate of the failed pixel cell is turned off; and repair information is stored in the fuse latches.

7. The imaging device of claim 1, wherein the pixel column includes multiple pixel cells and multiple access devices; and multiple pixel cells are connected to multiple access devices; and multiple access devices are connected to the column line; and failed pixel cell is replaced with un-failed pixel cell by turning on the transfer gate of the un-failed pixel cell while the transfer gate of the failed pixel cell is turned off; and repair information is stored in the fuse latches.

8. The imaging device of claim 1, wherein the pixel column includes multiple pixel cells and multiple access devices; and multiple access devices are connected to the column line; and failed access device is replaced with un-failed access device; and repair information is stored in the fuse latches.

9. The imaging device of claim 1, wherein the pixel cell includes a photo detector, a transfer transistor and a capacitor.

10. The imaging device of claim 1, wherein the photo detector is p-n diode.

11. The imaging device of claim 1, wherein the photo detector is p-i-n diode.

12. The imaging device of claim 1, wherein the photo detector is amorphous silicon photo detector.

13. The imaging device of claim 1, wherein the photo detector is polycrystalline silicon photo detector.

14. The imaging device of claim 1, wherein the photo detector is quantum dot photo-detector.

15. The imaging device of claim 1, wherein the photo detector is formed on the access device.

16. The imaging device of claim 1, wherein the photo detector configures finger-like shape to replace failed photo detector with un-failed photo detector.

17. The imaging device of claim 1, wherein the access device is formed on the bulk wafer.

18. The imaging device of claim 1, wherein the access device is formed on the SOI wafer.

19. The imaging device of claim 1, wherein the fuse latches include laser-blown fuses.

20. The imaging device of claim 1, wherein the fuse latches include electric fuses.
